(19) United States
(12) Patent Application Publication
(10) Pub. No.: US 2014/0175587 A1
(43) Pub. Date: Jun. 26, 2014

(54) DEVICES AND METHODS FOR ABSORBING LIGHT

(71) Applicants: Nicholas Ekins-Daukes, Kent (GB); Chrisopher Clement Phillips, London (GB)

(72) Inventors: Nicholas Ekins-Daukes, Kent (GB); Chrisopher Clement Phillips, London (GB)

(73) Assignee: IMPERIAL INNOVATIONS LIMITED, London (UK)

(21) Appl. No.: 13/876,521

(22) PCT Filed: Sep. 28, 2011
(86) PCT No.: PCT/GB2011/001413

§ 371 Date: Jun. 3, 2013

(30) Foreign Application Priority Data
Sep. 30, 2010 (GB) 1016489.5

(51) Int. Cl. H01L 31/0232; H01L 31/18

(52) U.S. Cl. CPC H01L 31/0232; H01L 31/18
USPC 257/432; 257/436; 438/72

(57) ABSTRACT

A light-absorbing device and method employ a series of photon-absorbing semiconductor substructures. A first semiconductor substructure provides first and second energy states. A difference between the first and second states being such as to cause an electron to be promoted from the first state to the second state upon absorption of a photon of a first energy. A second semiconductor substructure provides third and fourth energy states. The third state is arranged to receive the electron from the second state. A difference between the third and fourth states being such as to cause the electron to be promoted from the third state to the fourth state upon absorption of a subsequent photon of a second energy. The third state has a lower energy than the second state, such as to cause the electron to dissipate energy as it passes from the second state to the third state.

This invention relates to light absorbing devices, and methods of absorbing light. The invention is particularly applicable to photovoltaic devices, in which photons of light are absorbed to create electricity. However, the invention can also be applied to devices arranged to absorb photons of incoming light and then re-emit photons at a higher energy.

### BACKGROUND TO THE INVENTION

Commercial photovoltaic technologies presently rely upon processing silicon wafers into solar panels, essentially lifting proven techniques from the microelectronics industry and applying them to the problem of manufacturing cost effective solar panels. These processes have resulted in panel technologies with conversion efficiencies ranging from 5-20%. Incremental improvements in these conventional technologies are likely to result in modest improvements in efficiency towards 20%, with an aim to reach an installed cost of US$2/W. Cost projections indicate that the installation cost will start to dominate price of the solar installation from 2015, so raising the efficiency—namely increasing the amount of electrical power for each installed unit—is the only technological route for substantially reducing the cost of photovoltaic electricity.

A conventional single junction solar cell operates by absorbing light of a specific frequency v, having photons of a specific corresponding energy E (by virtue of the relationship E=hv, where h is Planck's constant). The absorption of such photons causes electrons from the valence band to be promoted to the conduction band of the semiconductor material from which the junction is formed, across a bandgap of corresponding magnitude E_{g}, and this in turn causes an electric current to be produced. However, incident light is seldom monochromatic, and indeed, with sunlight, a wide spectrum of frequencies is present. With incident photons having energies less than the specific energy E_{g} (i.e. lower frequency, longer wavelength light), the photons will not be absorbed and their energy will be lost. For incident photons having energies higher than the specific energy E_{g} (i.e. higher frequency, shorter wavelength light), the photogenerated electrons will scatter, resulting in incomplete conversion into electrical energy and again loss of energy. Due to the fundamental operation of conventional single-junction solar cells, the efficiency can never rise above 31% (for a single bandgap junction and the standard spectrum of frequencies emitted by the sun), so technologies that are already at 20% are close to their practical limit.

Integrating several semiconductor absorbers into a ‘multi-junction’ solar cell, having junctions tuned to different frequencies of light, raises the theoretical efficiency limit to 87%. The present state of the art is a triple junction solar cell that has attained an efficiency of 41.8% (Spectrolab, USA). Such solar cells are suitable for use in solar concentrator systems where light is collected by large mirrors and directed onto small but highly efficient solar cells, and also on spacecraft where high cell cost can be tolerated.

This concentrator approach can become very cost effective if the efficiency of the solar cell is high. FIG. 1 (from King et al., Proc. 22nd EUPVSEC, 2007) shows a calculation of the cost of electricity as a function of cell cost. Typical values for crystalline silicon are indicated by the shaded vertical band towards the left of the figure, which when including balance of systems (DOS) costs yield system costs in the region of US$2.5/W for existing 15-20% systems. Assuming a 25% panel can be manufactured in volume, which will be a stretch for the industry, the system cost could be lowered to US$2/W but no further. While concentrator systems have very much higher cell costs, indicated by the shaded vertical band at the right of the figure, their use of high efficiency solar cells can lead to installed system costs of US$1/W, which is significantly lower than flat plate photovoltaic technology.

The present triple junction solar cell technology is manufactured at around US$10/cm² and achieves an efficiency of 37%, leading to a system cost of approximately US$2/W. Participants in this market currently have plans to reach 45% efficiency. To significantly increase efficiency, beyond 50%, a four junction solar cell would be required, but there are great challenges in achieving this as there is no high-performance semiconductor alloy that can be used to fabricate the fourth junction.

Another issue with multi-junction solar cells is that the different junctions need to be arranged such that the constituent photons in the incident light are absorbed sequentially by wavelength. That is to say, short wavelength light (i.e. in the blue region) should be absorbed by a first junction, and then light of an intermediate wavelength (i.e. green) by a second junction, and then long wavelength light (i.e. red) by a third junction. This gives rise to a multilayer structure in which the different semiconductor junctions are stacked on top of one another in sequence. However, difficulties are encountered when fabricating semiconductor crystals in a multilayer structure, including epitaxial strain effects, the need to maintain good crystal quality throughout the layers, and the need for current matching.

Thus, there is a desire to incorporate a large number of junctions into a solar cell structure, enabling the 87% efficiency limit to be approached without the constraints of finding new semiconductor materials for each junction, or the problems that are encountered when fabricating different semiconductor layers in a conventional multi-junction multilayer structure. By increasing the efficiency of the solar cell structure, this would enable a greater output voltage to be produced for a given amount of incident light.

There is also a desire to produce a device which can efficiently absorb photons over a range of energies and re-emit photons at a higher energy.

Background art is provided by U.S. Pat. No. 6,444,897 B1, and a review paper entitled “The Intermediate Band Solar Cell: Progress Toward the Realization of an Attractive Concept” by Luque and Marti (Adv. Mater. 2010, 22, pages 160-174, published online on 9 Nov. 2009).

U.S. Pat. No. 6,444,897 B1 describes a theoretical concept for producing a solar cell using a semiconductor having a valence band, a conduction band, and an intermediate band between the valence and conduction bands. It is suggested that the intermediate band may be produced by fabricating quantum dots with the wave functions of the electrons corresponding to the intermediate level. It is proposed that high energy photons (i.e. of high frequency light) will promote electrons from the valence band directly up to the conduction band, whilst lower energy photons (i.e. of lower frequency light) will promote electrons from the valence band to the intermediate band, or from the intermediate band to the conduction band. By virtue of the intermediate band, U.S. Pat. No. 6,444,897 B1 thereby provides a principle by which an electron can be progressively excited up a “ladder” of energy states, upon sequentially absorbing low energy photos. In theory, this enables a single solar cell structure to generate electricity from photons of different frequencies.

However, in practice, the concept proposed in U.S. Pat. No. 6,444,897 B1 has not been found to produce the high conversion efficiencies that were hoped for. This is discussed in the above-referenced Advanced Materials (Adv. Mater.) review paper by Luque and Marti, both of whom are inventors of U.S. Pat. No. 6,444,897 B1 Luque and Marti mention that, to the best of their knowledge, the highest published efficiency obtained using the principle of sequential absorption of photons is 18.3%. This is far removed from the ultimate theoretical goal of 87% efficiency towards which the academic and industrial community is striving, or a theoretical limit of 63% for intermediate band cells.

There is therefore a strong desire to improve the efficiency of such a process in which sequentially absorbed photons are used to progressively excite electrons.

### SUMMARY OF THE INVENTION

According to a first aspect of the present invention there is provided a light-absorbing device as defined in Claim 1 of the appended claims. Thus there is provided a light-absorbing device comprising a series of photon-absorbing semiconductor substructures, the device comprising: a first semiconductor substructure providing first and second energy states, the difference between the first and second energy states being such as to cause an electron to be promoted from the first energy state to the second energy state upon absorption of a photon of a first energy; and a second semiconductor substructure providing third and fourth energy states, the third energy state being arranged to receive the electron from the second energy state, and the difference between the third and fourth energy states being such as to cause the electron to be promoted from the third energy state to the fourth energy state upon absorption of a subsequent photon of a second energy; wherein the third energy state has a lower energy than the second energy state, such as to cause the electron to dissipate energy as it passes from the second energy state to the third energy state.

The term “semiconductor substructure” should be interpreted broadly, to encompass a semiconductor crystal or a region thereof having characteristics (in particular, energy states into which electrons can be excited) distinguishable from those of one or more other such substructures in the device. The semiconductor substructures may be formed as layers, and may differ from one another as a result of variations in layer thickness, differences in semiconductor alloying elements, and so on.

By virtue of the first semiconductor substructure providing first and second energy states for absorption of a photon of a first energy, and the second semiconductor substructure providing third and fourth energy states for absorption of a subsequent photon of a second energy, with the third state being arranged to receive the electron (already excited by the first photon) from the second energy state, this enables the sequential absorption of photons, causing sequential excitation of the electron in a manner similar to that proposed in U.S. Pat. No. 6,444,897 B1.

However, significantly different from U.S. Pat. No. 6,444,897 B1, the third energy state has a lower energy than the second energy state, causing the electron to dissipate energy as it passes from the second energy state to the third energy state. Although this process, which we refer to as our “Photon Ratchet” concept, loses some energy, it provides the considerable advantage of “locking” the electron into the excited (third) energy state, ensuring (or at least considerably increasing the probability) that its lifetime there is long enough to enable the subsequent absorption event to take place. Thus, the time for which the electron is in the excited (third) energy state is much longer than would be the case with the intermediate band in U.S. Pat. No. 6,444,897 B1. As a consequence, the electron has a higher probability of absorbing a subsequent photon and undergoing further excitation.

Our Photon Ratchet principle can readily be extended across the solar spectrum, and enables the maximum energy to be extracted from each photon absorbed. This approach enables the device to reach high efficiency.

In our view, our ratchet step is the key to making the sequential absorption process efficient. If the ratchet step is omitted (as is the case in U.S. Pat. No. 6,444,897 B1) then the excited electron will quickly return to the state it was excited from, making it unlikely that the intermediate level is occupied, and hence producing only weak sequential absorption. We believe this is a key reason why the experimental tests documented by Luque and Marti in the above-referenced Advanced Materials paper yielded only low efficiencies.

Although only first and second semiconductor substructures have been mentioned above, it will be appreciated that many such substructures may be employed in a practical device. Each semiconductor substructure would be designed to absorb photons of different specific energy, over a wide spectrum of wavelengths. The excited electron is passed from the excited state of each substructure to the ground state of the next, and thereby undergoes sequential excitation up a “ladder” of energy states, in correspondence with the sequential absorption of the photons.

Preferable, optional, features are defined in the dependent claims.

Thus, preferably the difference between the first and second energy states is greater than the difference between the third and fourth energy states, such that the photon of the first energy is of greater energy than the photon of the second energy. Thus, a high energy (shorter wavelength) photon is absorbed first, followed by a lower energy (longer wavelength) photon. This is a more efficient absorption sequence than would be the case if the lower energy photon were absorbed before the higher energy one.

The first and second semiconductor substructures may comprise layers of the order of nanometres in thickness. Such layers are thin enough to act as quantum wells.

The first and second semiconductor substructures may each comprise a plurality of layers.

The different energy states of the first and second semiconductor substructures may be as a result of the first semiconductor substructure having a different layer thickness from the second semiconductor substructure.

Alternatively, or in addition, the different energy states of the first and second semiconductor substructures may be as a result of the first semiconductor substructure having a different atomic composition from the second semiconductor substructure.

The device may further comprise a chirped superlattice between the first and second semiconductor substructures, to improve the speed and efficiency of the ratcheting process.

Alternatively, or in addition, the device may incorporate one or more electron mirrors to block the passage of electrons in a certain energy range and to reflect them back in the opposite direction, again to improve the speed and efficiency of the ratcheting process.

According to a second aspect of the present invention there is provided a method of absorbing light, the method comprising: absorbing a photon of a first energy using a first semiconductor substructure having first and second energy states, the difference between the first and second energy states being such that an electron is promoted from the first energy state to the second energy state; transferring the electron from the second energy state to a third energy state, the third energy state being provided by a second semiconductor substructure, the third energy state having a lower energy than the second energy state such as to cause the electron to dissipate energy as it passes from the second energy state to the third energy state; and absorbing a subsequent photon of a second energy using the said second semiconductor substructure having the said third energy state and a fourth energy state, the difference between the third and fourth energy states being such that the electron is promoted from the third energy state to the fourth energy state.

The method may further comprise sending the excited electron around an electrical circuit.

Alternatively, the method may further comprise allowing the excited electron to relax and thereby emit a photon of an energy higher than that of any of the photons that were absorbed.

With both aspects of the invention, preferable, optional, features are defined in the dependent claims.

### BRIEF DESCRIPTION OF THE DRAWINGS

Embodiments of the invention will now be described, by way of example only, and with reference to the drawings in which:

FIG. 1 illustrates the dependency of the cost of electricity plotted both as kWh/year and photovoltaic system cost in US$/W as a function of cell cost, with the shaded vertical band towards the left of the figure indicating the cell manufacturing costs for fixed flat plate technology, and the 500X point focus band at the right of the figure indicating the cell manufacturing cost for highly efficient solar cells based on III-V semiconductors;

FIG. 2 illustrates a first embodiment of our “Photon Ratchet” sequential absorption technique, where the absorption of a high energy blue photon (the upward arrow towards the left of the figure) drives an electron into a state where it can absorb the energy of a lower energy green photon (the upward arrow in the centre of the figure), and then in turn absorbs the energy of an even lower energy red photon (the upward arrow towards the right of the figure), with a partial relaxation process (our “ratchet” step) between each sequential absorption event;

FIG. 3 shows an alternative embodiment of the arrangement of FIG. 2, where high energy photons are absorbed via an interband transition, while absorption of lower energy photons takes place with inter-sub-band transitions; and

FIG. 4 shows another alternative embodiment of the arrangement of FIG. 2, where the initial relaxation step is eliminated and replaced by a degenerately doped semiconductor, ensuring high occupancy of the ground state.

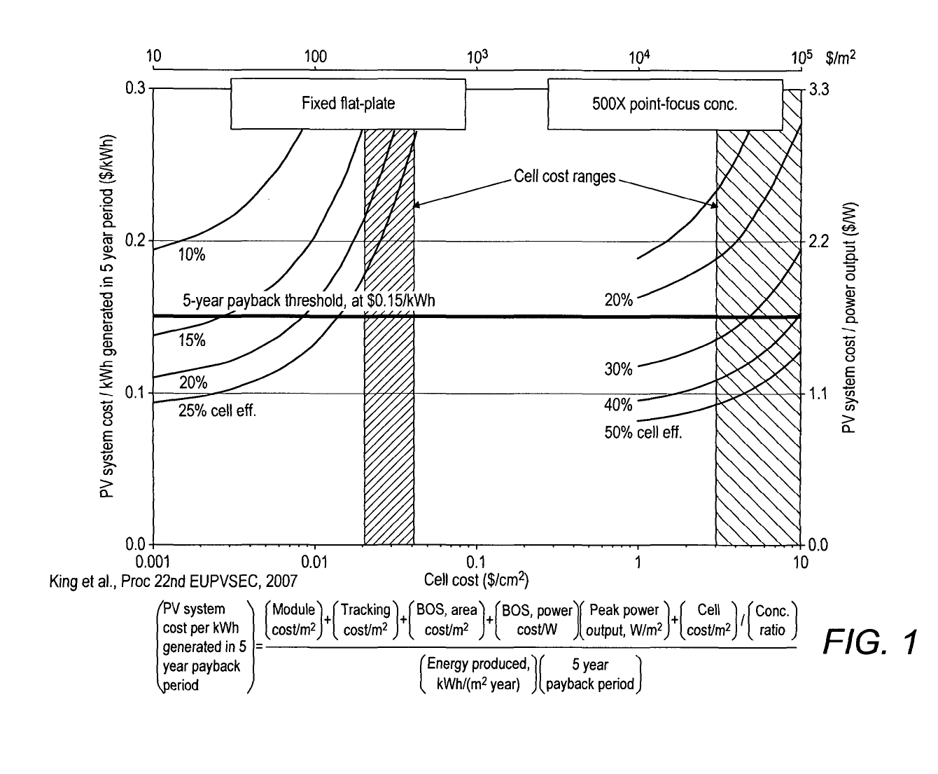

In the figures, like elements are indicated by like reference symbols throughout.

### DETAILED DESCRIPTION OF PREFERRED EMBODIMENTS

The present embodiments represent the best ways known to the applicants of putting the invention into practice. However, they are not the only ways in which this can be achieved.

The difficulty in achieving an efficient solar cell stems from the solar spectrum being very broad in its energy content; photons should ideally be collected from the ultraviolet to the infra-red. The embodiments of the present invention use quantum design to produce semiconductor substructures that enable sequential absorption of photons across a spectrum of energies. In our sequential absorption techniques, a photon of a first energy is first absorbed, causing promotion of an electron in a first semiconductor substructure from one energy state to another. The electron is then transferred to the ground state of a second semiconductor substructure, and a photon of a second energy is absorbed, causing further promotion of the electron to a higher energy state in the second semiconductor substructure. Preferably the photon that is first absorbed is of a relatively high energy, and the subsequent photon (of a second energy) absorbed is of a lower energy. In a similar manner, photons of progressively lower energies may be absorbed in further semiconductor substructures, each causing further promotion of the electron to even higher energy states. Following each absorption event, our “Photon Ratchet” partial relaxation technique is employed, to “lock” the electron into the excited state, and to prevent rapid complete relaxation from occurring between the absorption events. Similar to a mechanical ratchet, a key step in this process is a small loss in energy that enables the energy of the absorbed photon to be preserved for a long period of time.

Although, in preferred embodiments of the invention, a relatively high energy photon is absorbed first, followed by photons of progressively lower energies, this is not essential. Indeed, in alternative embodiments, lower energy photons could be absorbed first, followed by higher energy ones. Absorbing high energy photons first is considered to be more efficient, though. In either case, our Photon Ratchet concept is used to lock the electron into the excited state following each absorption event.

With our Photon Ratchet concept, each photon that is absorbed “ratchets” the energy of an electron through a specifically designed structure. Preferably a series of semiconductor crystal substructures are provided, each of which is “tuned” by quantum design to absorb photons of a specific energy.

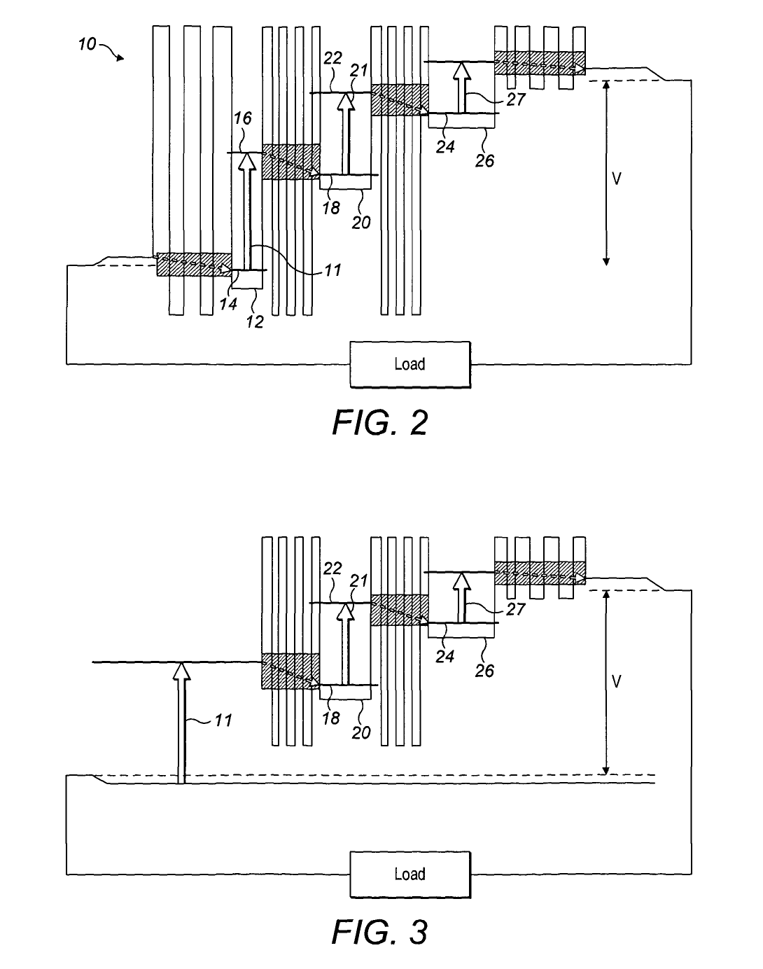

FIG. 2 illustrates a first embodiment of our Photon Ratchet concept, using quantum wells. Here, a sequential absorber device 10 is constructed from a series of coupled electronic states, but allowing for partial relaxation of the electron between successive absorption events. We start with absorption of a blue photon 11 in a quantum well 12 that is specifically configured to absorb such a photon. This promotes an electron in energy from a first (ground) state 14 to a second (excited) state 16. That electron then undergoes a very fast relaxation process (white dotted arrow) to a third (ground) state 18 provided by a second absorbing well 20 that is specifically configured to absorb a green photon. The electron can then absorb the energy of a green photon 21, causing it to be promoted to a fourth (even higher) energy state 22. Again, this is followed by a fast relaxation step into the ground state 24 of a third absorbing well 26 that is specifically configured to absorb a red photon. Absorption of a red photon 27 and subsequent relaxation takes place to transport the electron to an electrical contact, from which it may enter an electrical circuit.

Thus, the Photon Ratchet absorbs a photon, generating an electron-hole pair, followed by an energy relaxation (dissipation) step. This relaxation step locks the electron into the ground state of a second absorber, from which it undergoes a subsequent absorption step, and the process repeats.

As with any ratchet, the locking mechanism inevitably introduces some loss into the solar cell, but this is greatly compensated by the ability to absorb the broad solar spectrum, extracting the maximum energy from each photon absorbed. It is the multitude of different ratchet steps (only three are depicted in FIG. 2, but many more are possible) that enables this approach to reach high efficiency.

The important feature is the ratcheting of the electron up a ladder of states, with each step becoming locked via relaxation of energy (white dotted arrows) following absorption of photons. This is used to lock the electron into each energy state, ensuring that its lifetime is long enough to enable the subsequent absorption event to take place. As those skilled in the art will appreciate, during each partial relaxation event the energy dissipated by the electron should be greater than kT (where k is Boltzmann's constant and T is the absolute temperature)—for example 3kT or more—in order to prevent the electron from travelling backwards over each “ratchet” as a result of thermal excitation.

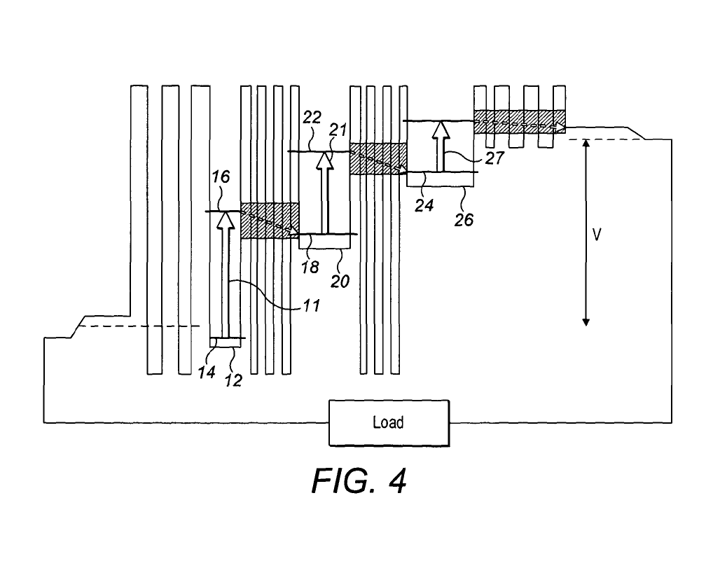

It should be noted that, in FIG. 2, a preliminary ratcheting step is included before the first (e.g. blue) photon absorption event 11. This preliminary ratcheting step is optional, as this could also be achieved by doping the semiconductor to ensure the ground state 14 for the blue transition is filled. As discussed below, in FIGS. 3 and 4, the preliminary ratcheting step has been omitted.

A final ratcheting step, after the final (e.g. red) photon absorption event 27, is recommended, though, in order to prevent recombination (reverse of absorption) from quickly returning the electron to the ground state 24 of the final transition.

FIG. 3 shows an alternative embodiment of the arrangement of FIG. 2, where high energy photons 11 are absorbed via an interband transition, while absorption of lower energy photons 21, 27 takes place with inter-sub-band transitions. Combining these two types of optical transition allows the absorption of different optical wavelengths to be engineered with increased freedom and precision, because the interband process absorbs a wide range of wavelengths, whereas the inter-sub-band process absorbs a much narrower range of wavelengths, but in an energy range that can be chosen with greater freedom.

FIG. 4 shows another alternative embodiment of the arrangement of FIG. 2, where the initial relaxation step is eliminated and replaced by a degenerately doped semiconductor, ensuring high occupancy of the ground state 14. This doping technique removes the need for the first of the ratchet steps shown in FIG. 2, and thus offers improved recovery of the energy contained in the absorbed light.

Materials

The overall structure of such a device can be made from semiconductor materials, structured on the nanoscale, configured to absorb photons using interband or inter-sub-band transitions. For example, the device may comprise a series of narrow crystal layers, wherein the thickness of each layer and/or the constituent atoms in each layer provide a specific bandgap configured to absorb photons of a specific energy. The thickness of the crystal layers and/or the constituent atoms in the layers are varied through the device, thereby enabling photons of progressively lower energies to be absorbed (i.e. blue, green and then red).

Ideally, the thickness of the crystal layers and/or the constituent atoms in the layers are selected such that the optical transitions are matched to the solar spectrum. A suitable material that enables very deep quantum wells to be formed may be used. In the near term, these materials could be III-V semiconductors, as excellent deposition technology exists for this material system. Ultimately this technique could be implemented in a Si/SiO₂/SiN material, highlighting the possibility for a low-cost and abundant material system to be used. Other possible materials include alloys of GaN, AlN, InN, etc.

The speed and efficiency of the ratcheting process can be improved by incorporating a chirped superlattice in the region of material linking the first semiconductor substructure to the second semiconductor substructure. The chirped superlattice provides a ramp of closely spaced energy levels, each being of the order of a phonon energy, for example. The electrons scatter down this ramp at high speed, moving from the second energy state to the third energy state with improved efficiency.

The speed and efficiency of the ratcheting process can be further improved by incorporating electron mirrors into the device. These electron mirrors are multilayer structures that use quantum mechanical principles to block the passage of electrons in a certain energy range, and reflect them back in the opposite direction. A series of electron mirrors, suitably placed throughout the structure, and designed to reflect electrons of appropriate energies, can be used to improve the overall device efficiency by effectively pushing the electrons in the desired direction.

Fabricating and Tuning the Semiconductor Substructures

Each semiconductor substructure is designed to absorb photons of a different energy. The semiconductor substructures may be designed to extract specific parts of the solar spectrum, to optimise conversion of light into electricity, and to optimise strength of absorption.

The semiconductor substructures may be formed as layers of the order of nanometres in thickness. These may be fabricated using known semiconductor deposition techniques such as Molecular Beam Epitaxy (MBE) and Metal Organic Vapour Phase Epitaxy (MOVPE). As those skilled in the art of quantum design will appreciate, each layer can serve as a quantum well, and the bandgap (between the ground state and excited state) of each quantum well can be “tuned” by varying the thickness of the layer. The energy of the photon (and consequently wavelength of light) that each layer will absorb can therefore be specified by the thickness of the layer.

In practice, a number of layers (e.g. 10 to 20) may be deposited, all at the same period (i.e. thickness), to absorb light of one wavelength, and then a similar number may be deposited at another period, to absorb light of another wavelength.

Additionally, or instead of varying the layer thickness, the bandgap of the semiconductor substructures may be tuned by altering the atomic composition of the substructures. For example, the proportions of semiconductor alloying elements may be changed. For an infrared device, it is envisaged that indium gallium arsenide ([In,Ga]As,P) semiconductor alloys may be used to fabricate substructures having relatively low bandgaps, and aluminium gallium arsenide ([Al,In,Ga]As,P) semiconductor alloys may be used to fabricate substructures having relatively high bandgaps.

Alternatively for near infra-red or visible sub-systems, the AlInGaN semiconductor alloy could be used to fabricate substructures, where relatively deep AlInGaN layers with low or zero Al fraction are used to achieve low band-gap materials, while high Al but low or zero In fraction AlInGaN is used to fabricate higher band-gap material.

The Absorption Events

In each semiconductor substructure, the absorption event may be the promotion of an electron from once valence band to another, or from a valence band to a conduction band, or may be inter-sub-band transitions.

After the Sequential Absorption of the Photons

Following the sequential absorption processes the excited electrons can then be sent around an electrical circuit, dissipating their energy in an electrical load before being re-injected into the ground state of the first absorbing well for the cycle to repeat. Alternatively, the electrons can be allowed to relax and emit photons of an energy higher than that of any of the photons that were absorbed.

Advantages

The present approach dispenses with the need to marry together different materials to achieve a multi junction solar cell. In principle, it enables a solar cell with a very large number of sub-structures to be fabricated potentially from two materials, allowing the ultimate efficiency limit of 87% to be approached. It therefore sidesteps the problem faced by the conventional multi junction solar cell community that there is no convenient fourth semiconductor absorber to extend the triple junction solar cell to four junctions. Further, the approach is particularly well suited to enable a very large number of junctions to be incorporated into the solar cell.

One practical advantage is that the sequential optical transition process serves to increase the voltage of the solar cells. When there are several ratchet steps, the power delivered by the solar cell will be primarily as a high voltage at low current. This solves a problem which blights present concentrator solar cell technologies where large electrical currents must be extracted from the solar cell. To handle these large currents, a large quantity of opaque metal has to be deposited on the surface which shades the solar cell and thus reduces its efficiency. A high voltage solar cell would suffer less from this problem because a lower metal coverage is required in order to extract the smaller current.

Embodiments of the present invention may be employed in concentrator photovoltaic applications, and are also well suited to applications in space.

1. A light-absorbing device comprising a series of photon-absorbing semiconductor substructures, the device comprising:
a first semiconductor substructure providing first and second energy states, the difference between the first and second energy states being such as to cause an electron to be promoted from the first energy state to the second energy state upon absorption of a photon of a first energy; and
a second semiconductor substructure providing third and fourth energy states, the third energy state being arranged to receive the electron from the second energy state, and the difference between the third and fourth energy states being such as to cause the electron to be promoted from the third energy state to the fourth energy state upon absorption of a subsequent photon of a second energy;
wherein the third energy state has a lower energy than the second energy state, such as to cause the electron to dissipate energy as it passes from the second energy state to the third energy state.

2. A device as claimed in claim 1, wherein the difference between the first and second energy states is greater than the difference between the third and fourth energy states.

3. A device as claimed in claim 1, wherein the first and second semiconductor substructures comprise layers of the order of nanometers in thickness.

4. A device as claimed in claim 3, wherein the first and second semiconductor substructures each comprise a plurality of layers.

5. A device as claimed in claim 3, wherein the different energy states of the first and second semiconductor substructures are as a result of the first semiconductor substructure having a different layer thickness from the second semiconductor substructure.

6. A device as claimed in claim 1, wherein the different energy states of the first and second semiconductor substructures are as a result of the first semiconductor substructure having a different atomic composition from the second semiconductor substructure.

7. A device as claimed in claim 1, further comprising a chirped superlattice between the first and second semiconductor substructures.

8. A device as claimed in claim 1, further incorporating one or more electron mirrors to block the passage of electrons in a certain energy range and to reflect them back in the opposite direction.

9. A method of absorbing light, the method comprising:
absorbing a photon of a first energy using a first semiconductor substructure having first and second energy states, the difference between the first and second energy states being such that an electron is promoted from the first energy state to the second energy state;
transferring the electron from the second energy state to a third energy state, the third energy state being provided by a second semiconductor substructure, the third energy state having a lower energy than the second energy state such as to cause the electron to dissipate energy as it passes from the second energy state to the third energy state; and
absorbing a subsequent photon of a second energy using the said second semiconductor substructure having the said third energy state and a fourth energy state, the difference between the third and fourth energy states being such that the electron is promoted from the third energy state to the fourth energy state.

10. A method as claimed in claim 9, wherein the difference between the first and second energy states is greater than the difference between the third and fourth energy states.

11. A method as claimed in claim 9, wherein the first and second semiconductor substructures comprise layers of the order of nanometers in thickness.

12. A method as claimed in claim 11, wherein the first and second semiconductor substructures each comprise a plurality of layers.

13. A method as claimed in claim 11, wherein the different energy states of the first and second semiconductor substructures are as a result of the first semiconductor substructure having a different layer thickness from the second semiconductor substructure.

14. A method as claimed in claim 9, wherein the different energy states of the first and second semiconductor substructures are as a result of the first semiconductor substructure having a different atomic composition from the second semiconductor substructure.

15. A method as claimed in claim 9, wherein the electron scatters down a succession of closely-spaced energy levels provided by a chirped superlattice when it is transferred from the second energy state to the third energy state.

16. A method as claimed in claim 9, further comprising using one or more electron mirrors to block the passage of electrons in a certain energy range and to reflect them back in the opposite direction.

17. A method as claimed in claim 9, further comprising sending the excited electron around an electrical circuit.

18. A method as claimed in claim 9, further comprising allowing the excited electron to relax and thereby emit a photon of an energy higher than that of any of the photons that were absorbed.

19. (canceled)

20. (canceled)
